(19) United States
(12) Patent Application Publication
(10) Pub. No.: US 2023/0049007 A1
(43) Pub. Date: Feb. 16, 2023

(54) STRUCTURES FOR MICRO LED LASER RELEASE

(71) Applicant: Intel Corporation, Santa Clara, CA (US)

(72) Inventors: Khaled Ahmed, San Jose, CA (US); Anna M. Prakash, Chandler, AZ (US); Ronald C. Woodbeck, Placerville, CA (US); Santosh Pabba, Hillsboro, OR (US)

(73) Assignee: Intel Corporation, Santa Clara, CA (US)

(21) Appl. No.: 17/402,313

(22) Filed: Aug. 13, 2021

(51) Int. Cl. H01L 33/00; H01L 21/683; H01L 33/62; H01L 33/60; H01L 33/20

(52) U.S. Cl. CPC H01L 33/005; H01L 21/6835; H01L 33/62; H01L 33/60; H01L 33/20; H01L 33/06

(57) ABSTRACT

Micro light-emitting diodes (LED) are distanced from a mirror layer that reflects light emitted by the LEDs to increase the light extraction efficiency of the LEDs. In some embodiments, micro LEDs are electrically coupled to the mirror layer by vias positioned at an end of the LED positioned proximate to the mirror layer. In other embodiments, a conductive layer is positioned adjacent to an electrode of multiple micro LEDs and a pillar contacts the conductive layer at a location where the conductive layer is not positioned adjacent to a micro LED electrode. Vias and pillars allow the mirror height to be increased relative to structures where micro LEDs extend into a mirror layer. Increasing the mirror height can reduce the amount of destructive interference at a release layer caused by reflections of LED-emitted light by the mirror layer when the release layer is ablated via laser irradiation.

### BACKGROUND

To enable the transfer of micro light emitted diodes (LEDs) from a substrate upon which the micro LEDs were formed, such as a wafer, to another component, the micro LEDs can be formed with a release layer between the micro LEDs and the substrate. Micro LEDs can be transferred from the substrate to the other component by attaching to the substrate to the other component and ablating the release layer via laser irradiation, which causes the micro LEDs to be separated from the substrate.

### BRIEF DESCRIPTION OF THE DRAWINGS

FIG. 1 illustrates an example structure comprising pyramid LEDs distanced from a mirror layer and electrically coupled to the mirror layer by vias.

FIG. 2 illustrates an example structure in which LEDs extend into a mirror layer.

FIG. 3 illustrates an example structure comprising pyramid LEDs distanced from a mirror layer and electrically coupled to the mirror layer by pillars.

FIG. 4 illustrates an example structure comprising nanowire LEDs distanced from a mirror layer and electrically coupled to the mirror layer by vias.

FIG. 5 illustrates an example structure comprising nanowire LEDs distanced from a mirror layer and electrically coupled to the mirror layer by pillars.

FIG. 6 illustrates an example arrangement of pillars among a plurality of LEDs.

FIGS. 7A-7D illustrate an example process of transferring pyramid LEDs electrically coupled to a mirror layer with vias from a source substrate to a display backplane.

FIG. 8 is an example computing system comprising structures with LEDs electrically coupled to a mirror layer by vias or pillars

FIG. 9 is a first example method for forming structures comprising LEDs.

FIG. 10 is a second example method for forming structures comprising LEDs.

FIG. 11 is a block diagram of an example computing system in which technologies described herein may be implemented.

### DETAILED DESCRIPTION

Micro light-emitting diodes (LEDs) are an attractive alternative to organic LEDs (OLEDs) in direct view displays due to their longer lifespans and greater brightness capacity. The manufacture of displays (or any other device) comprising micro LEDs may involve the transfer of micro LEDs from the substrate upon which the micro LEDs were formed, such as a silicon wafer, to a component of an end product, such as a display backplane. In some existing approaches, micro LEDs can be transferred by attaching a processed substrate comprising the micro LEDs to another component and then ablating a release layer positioned between the micro LEDs and the substrate through laser irradiation. In some instances, a processed substrate comprising micro LEDs comprises a mirror layer that reflects visible light emitted by the micro LEDs to increase the light extraction efficiency of the micro LEDs. However, the reflected light can cause destructive interference at the laser release layer and adversely impact the yield of releasing micro LEDs from the substrate (LED release yield).

In some existing approaches where a mirror layer is utilized to increase micro LED light extraction efficiency, a portion of the micro LEDs extends into the mirror layer and the electrically conductive mirror layer provides an anode or cathode signal for the micro LEDs. The technologies described herein position a mirror layer proximate to and distanced from the micro LEDs. This results in the reduction of interference at the laser release layer caused by the mirror layer relative to approaches where a portion of the micro LEDs extend into the mirror layer. The reduction in destructive interference at the release layer can improve LED release yield. The addition of conductive structures (e.g., vias, pillars) that electrically couple the mirror layer to the micro LEDs (or to a conductive layer that is electrically coupled to a micro LED) allows the mirror layer to remain in electrical contact with the micro LEDs.

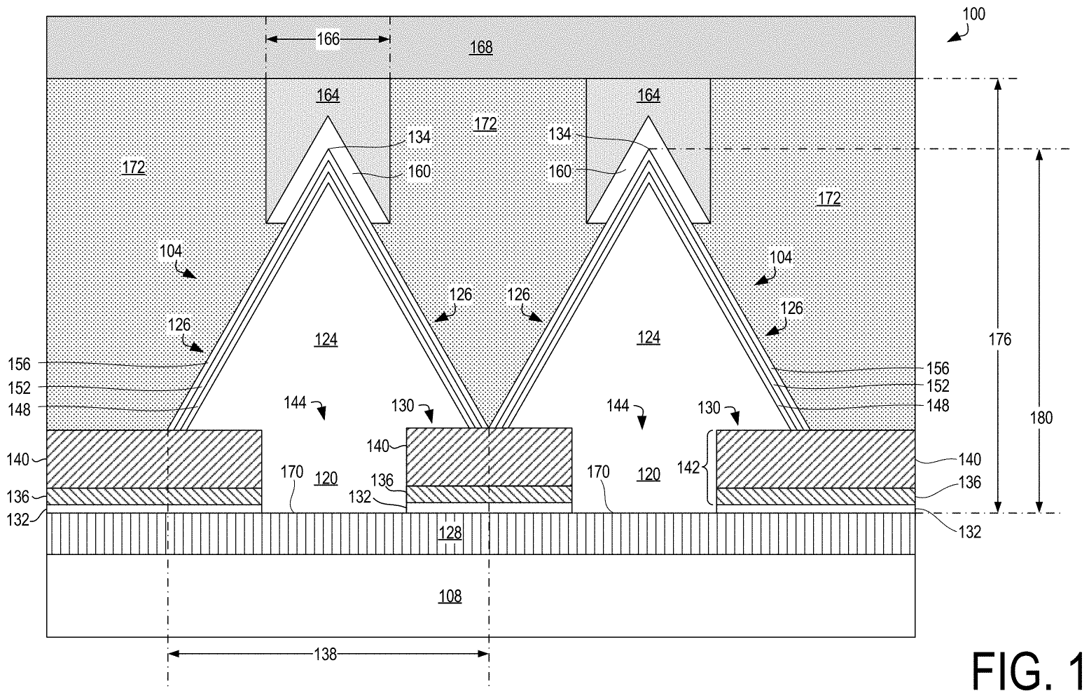

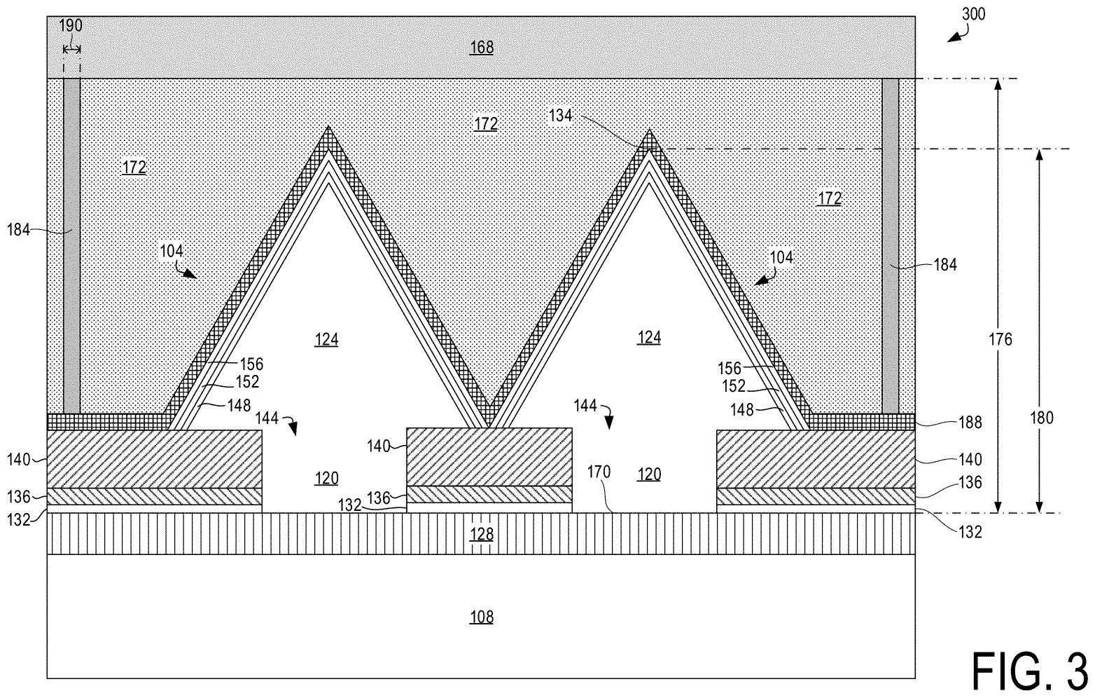

As used herein, the phrase “electrically coupled” refers to components that are coupled to facilitate the flow of current between them. For example, with reference to FIGS. 1 and 3, the micro LEDs 104 are electrically coupled to the layer 168 due to the presence of conductive components (adhesion layers 160 plus vias 164 in FIG. 1, a conductive layer 188 and pillars 184 in FIG. 3) between the micro LEDs 104 and the layer 168. As used herein, the phrase “electrically coupling” or “electrically couples” in reference to a component refers to a component that facilitates the flow of current between other components. For example, with reference to FIG. 1, a via 164 electrically couples a micro LED 104 to the layer 168 due to the conductive nature of the via 164 and the via 164 connecting the layer 168 to a conductive adhesion layer 160 that is, in turn, positioned adjacent to the micro LED 104.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. For example, with reference to FIG. 1, the micro LEDs 104 are located on the substrate 108 (with an intervening layer 128). As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y. As used herein, the term “about” in reference to a value of a feature (e.g., height, width, spacing) or upper and lower limits of a range of values for a feature includes features values that are within several percent of the stated feature value, feature value lower range limit, or feature value upper range limit.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, dimensions, spacings, or positions that vary slightly from the meaning of the unmodified term. A dimension that is “substantially uniform” over a region or area includes dimensions that vary slightly over the region or area. A dimension X that is “substantially N times” a dimension Y includes a dimension X that is within a few percent of N times dimension Y.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

FIG. 1 illustrates an example structure comprising pyramid LEDs distanced from a mirror layer and electrically coupled to the mirror layer by vias. The structure 100 comprises LEDs 104, which can be referred to as micro LEDs, located on a substrate 108. Vias 164 electrically couple the LEDs 104 to a mirror layer 168. The substrate 108 can be a silicon-on-sapphire substrate, a silicon substrate, or comprise a material that can be a base or substrate for the LEDs 104. The substrate 108 can be part of a wafer upon which a large number of LEDs 104 have been manufactured. The substrate 108 can be considered to be a source substrate as it is the substrate on which the LEDs 104 are formed and the substrate from which the LEDs 104 are transferred to another component. The LEDs 104 have a pyramid shape and can be referred to as pyramid LEDs or nanopyramid LEDs. A pyramid LED 104 comprises an LED stem 120, an LED body 124, a layer 148, a quantum well layer 152, and a p-electrode layer 156. A pyramid body 124 comprises multiple sides 126 that extend from a base 130 of a pyramid body 124 to an end 134 of the body 124 positioned proximate to and distanced from the mirror layer 168. An LED 104 further comprises an end 170 distal to the mirror layer 168.

In some embodiments, the pyramid bodies 124 can have a base diameter 138 that is about 3 um, about 5 um, about 10 um, or another size. In some embodiments, the base diameter 138 of the pyramid bodies 124 can be in the range of about 400-800 nm. The pyramid bodies 124 can have three, four, five, six, or another number of sides 126. In some embodiments, the LEDs bodies 124 are conical in shape.

A layer 128 positioned between the LEDs 104 and the substrate 108 can function as a nucleation layer for growing the pyramid stems 120. The layer 128 can comprise aluminum and nitride and can be aluminum nitride, aluminum scandium nitride, or another material that can function as a nucleation layer to grow the pyramid stems 120. In some embodiments, the layer 128 has a thickness in the range of about 20-30 nm. In some embodiments, the layer 128 has a thickness of about 25 nm.

A release layer 132 positioned adjacent to the layer 128 can be utilized in releasing the LEDs 104 from the substrate 108 via laser irradiation ablation. When the release layer 132 is irradiated with a laser, the release layer 132 can vaporize as it absorbs energy from the laser and the vaporization gas pressure results in the separation of the LEDs 104 from the substrate 108. In some embodiments, the LEDs 104 are released from the substrate 108 via the release layer 132 being irradiated with an infrared laser having a wavelength of about 1950 nm that is shone on the structure 100 from a side of the substrate 108 opposite to the side of the substrate 108 upon which the LEDs 104 are formed. The release layer 132 can comprise titanium nitride, niobium nitride, tantalum nitride, another metal nitride, or any other material suitable for use in releasing the LEDs 104 from the substrate 108 via laser irradiation. In some embodiments, the thickness of the release layer 132 can be in the range of about 5-50 nm. In other embodiments, the thickness of the release layer 132 can be in the range of about 10-30 nm.

Layers 136 and 140 together function as a mask used in the formation of the pyramid stems 120. That is, the layers 136 and 140 can be patterned as illustrated in FIG. 1 via a photolithography process and portions of the release layer 132 not covered by the patterned layers 136 and 140 stack can be removed by an etch process or another suitable process for removing exposed portions of the release layer 132. Layer 140 can comprise silicon and nitrogen and can be silicon nitride (e.g., Si₃N₄) or any other material that can function as a mask for the subsequent growth or deposition of gallium nitride and mask layer 136 can comprise silicon and oxygen and can comprise silicon dioxide or another material suitable for helping opening holes in the layer 140 during patterning of the layer 140. The layers 132, 136, and 140, as patterned in FIG. 1 define cavities 144. Although walls 142 of layers 140 and 136 adjacent to the cavities 144 are shown as being coplanar, in other embodiments, the walls 142 are not coplanar. For example, in some embodiments, the walls of layer 136 adjacent to the cavities 144 can extend further into the cavities 144 than the walls of the layer 140 and in other embodiments, the walls of the layer 140 can extend further into the cavities 144 than the walls of the layer 136. In some embodiments, only a single mask layer is used as a mask for subsequent growth or deposition of gallium nitride. The single mask layer can comprise silicon and nitrogen and can be silicon nitride or another material that can function as a mask for the subsequent growth or deposition of gallium nitride. In other embodiments, the layer 132 is not etched during the photolithography process that creates the holes in the layers 136 and 140 and the nanowire cores are grown out of the release layer 132.

Pyramid stems 120 are positioned in cavities 144 and pyramid bodies 124 are positioned above the layers 140 and the stems 120. The pyramid stems 120 can comprise gallium nitride doped with silicon or another n-type dopant that allows the stems 120 to function as growth seeds for the pyramid bodies 124. The pyramid bodies 124 can be comprised of n-type gallium nitride or another material that can function as a base to grow quantum wells that result in light emission from the LEDs 104. In some embodiments, the pyramid stems 120 and pyramid bodies 124 can be grown using a metalorganic vapor-phase epitaxy (MOVPE) process or another process that can grow stems 120 and pyramid bodies 124. MOVPE, also known as organometallic vapor-phase epitaxy (OMVPE) or metalorganic chemical vapor deposition (MOCVD), is a chemical vapor deposition method used to produce single or polycrystalline thin films and is a process for growing crystalline layers to create complex semiconductor multilayer structures.

Layers 148 are positioned adjacent to the pyramid bodies 124 and quantum well layers 152 are positioned adjacent to the layers 148. The layers 148 comprise aluminum, gallium, and nitride and can be aluminum gallium nitride. The quantum well layers 152 can comprise indium, gallium, and nitride and can be indium gallium nitride/gallium nitride quantum wells—layers comprising two or more gallium nitride layers with an indium gallium nitride layer positioned between adjacent gallium nitride layers. The layers 148 can control the trapping of electrons in the quantum wells 152 and the quantum wells 152 can determine the color of light generated by the LEDs 104. In some embodiments, layer 148 is undoped aluminum gallium nitride. In other embodiments, the LEDs 104 do not include layers 148 and the quantum well layers 152 are adjacent to the pyramid bodies 124. In some embodiments, the quantum well layers 152 can be grown using an MOVPE process or another process that can grow a quantum well layer over an LED body.

P-electrode layers 156 are positioned adjacent to the quantum well layers 152. The p-electrode layers 156 can comprise gallium and nitride and can be p-doped gallium nitride or another suitable material. The p-electrode layers 156 can help to provide holes to the quantum wells 152 to allow for the emission of light. In some embodiments, the p-electrode layers 156 can be grown using an MOVPE process or another that can grow p-gallium nitride layers 156 over indium gallium nitride/gallium nitride quantum wells 152. Adhesion layers 160 are positioned adjacent to ends 134 of the LEDs 104 (the points of the pyramid bodies 124) to aid in creating ohmic contacts to the p-electrode layers 156. The adhesion layers 160 can comprise nickel, palladium, platinum, silver, or another material that can aid in creating an ohmic contact to the p-electrode layers 156. In some embodiments, the adhesion layers 160 can be created using physical vapor deposition (PVD) or another suitable process.

The p-electrode layers 156 and the n-doped LED bodies 124 and stems 120 can be referred to as LED electrodes, with the p-electrode layers 156 being the anode electrodes and the n-doped LED bodies 124 and stems 120 being the cathode electrodes of the LEDs 104.

Vias 164 are positioned adjacent to the adhesion layers 160 and connect the adhesion layers 160 to a layer 168 that is positioned adjacent to the vias 164 and an insulating layer 172. The insulating layer 172 fills spaces between the layer 140, the LEDs 104, the vias 164 and the layer 168. The vias 164 can comprise copper, nickel, the same material as layer 168 (e.g., aluminum and silicon), or other suitable conductive material. The vias 164 can have a width 166 in the range of about 100-200 um.

The layer 168 reflects visible light emitted by the LEDs 104 back toward the LED stems 120 and thus acts as an optical mirror that can increase the light extraction efficiency of the LEDs 104. The layer 168 can be referred to as a mirror layer. In embodiments where the LEDs 104 are used in pixels of a direct view display, the layer 168 reflects light emitted by the LEDs 104 toward a viewer of the display. The layer 168 can comprise aluminum and silicon in ratios in the range of about 97-99% aluminum to about 1-3% silicon. The layer 168 can comprise aluminum and silicon in other ratios or comprise other suitable materials that allow the layer 168 to operate as an optical mirror for light emitted by the LEDs 104. In some embodiments, the layer 168 can be added over the insulating layer 172 and the vias 164 by sputtering, PVD, or another suitable process.

The insulating layer 172 can comprise silicon dioxide, silicon oxynitride, carbon-doped oxide, or another electrically insulating material that can serve as an electrical insulator. The insulating layer 172 can be added via plasma enhanced chemical vapor deposition (PECVD) or another suitable process. A planarization process such as chemical-mechanical polish (CMP) can be used to create a substantially uniform mirror height or optical cavity height over a substrate area, the mirror height or optical cavity as measured from the layer 168 to the end 170 of an LED (or to the surface of the layer abutting the LED stems 120 (e.g., layer 128)).

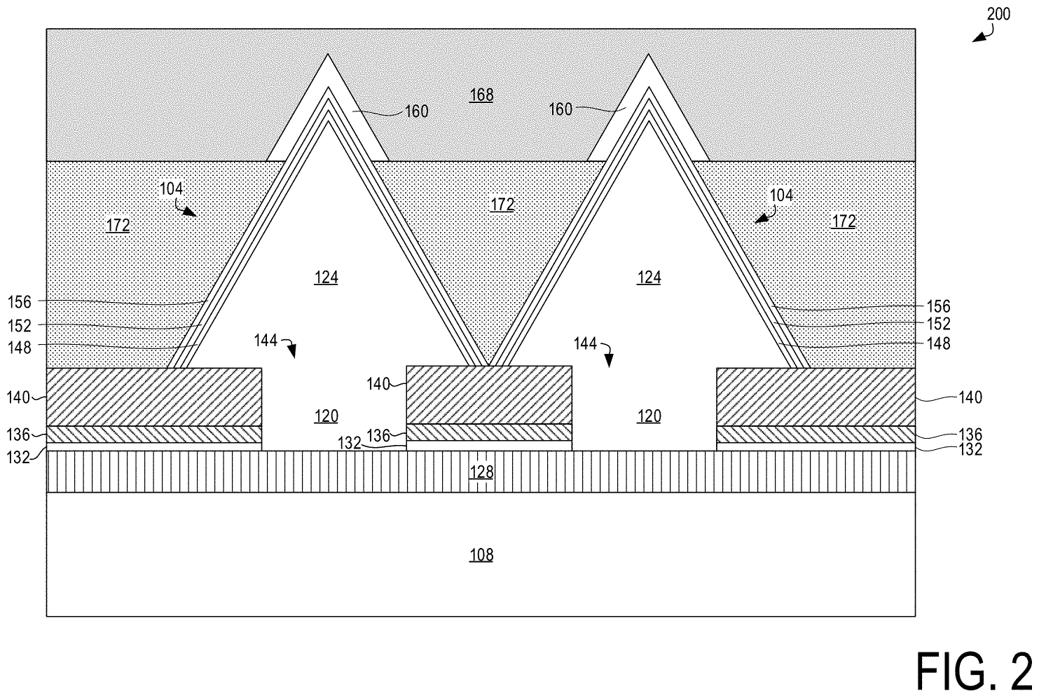

The presence of the vias 164 allows the LEDs 104 to be positioned proximate to and distanced from the layer 168. This is in contrast to structures in which micro LEDs extend into a mirror layer. FIG. 2 illustrates an example structure in which LEDs extend into a mirror layer. The structure 200 is similar to the structure 100 in FIG. 1 but does not comprise vias. The LEDs 104 in FIG. 2 are electrically coupled to the layer 168 through direct contact of the adhesion layers 160 to the layer 168. Thus, the layer 168 in FIG. 1 is distanced further away from the release layer 132 than the layer 168 in FIG. 2. This can result in the structure 100 having a higher LED release yield than the structure 200 due to light emitted by the LEDs 104 being reflected from the layer 168 causing less destructive interference at the release layer 132 during laser irradiation of the release layer 132.

Returning to FIG. 1, in some embodiments, a mirror height or optical cavity height 176 is greater than an LED height 180 as measured from an LED end 170 to an LED end 134. In some embodiments, the mirror height 176 can be substantially 1.1 times the LED height 180. In some embodiments, the mirror height 176 is about 900 nm.

FIG. 3 illustrates an example structure comprising pyramid LEDs distanced from a mirror layer and electrically coupled to the mirror layer by pillars. The structure 300 is similar to the structure 100 of FIG. 1 but with pillars 184 and a layer 188 that extends over the LEDs 104 providing the electrical coupling of the layer 168 to the LEDs 104 instead of vias (e.g., vias 164). The layer 188 is positioned between the insulating layer 172 and the p-electrode layer 156 and is transparent to allow light emitted by the LEDs 104 to reach the layer 168 and light reflected from the layer 168 to reach the LED stems 120. The layer 188 can comprise indium tin oxide (ITO) or other suitable conductive material that is transparent to visible light. The pillars 184 can comprise copper, nickel, the same material as layer 168 (e.g., aluminum and silicon), or other suitable material.

In some embodiments, the pillars 184 can have a width 190 in the range of about 100-800 nm. FIG. 3 illustrates two pillars 184 providing electrical coupling between the layer 168 and the p-electrode layers for two LEDs 104. This pillar frequency (one pillar for two pyramid LEDs) can be repeated throughout an array of LEDs that the LEDs 104 are a part of. In other embodiments, pillars can be placed between adjacent pyramid LEDs or positioned with N pyramid LEDs between pillars, where N can be any integer. Further, pillars could be positioned with N pyramid LEDs between pillars in more than one dimension. That is, pillars could be positioned with three pyramid LEDs between pillars in a first dimension (e.g., an x-dimension) and with three pyramid LEDs between pillars in a second dimension that is orthogonal to the first dimension (e.g., a y-dimension). In embodiments where the LEDs are used in display pixels, the pillar configuration can depend on the pixel design. For example, pillars can surround a plurality of LEDs used in a pixel. In another example, pillars can be located boundaries between adjacent pixels. It is not necessary that pillars be arranged periodically or regularly. Pillars can be arranged in any configuration among a plurality of LEDs.

In some embodiments, the pillars 184 can be formed as follows. After the formation of the p-electrode layers 156, the layer 188 is formed via blanket deposition of the material comprising the layer 188 (e.g., indium tin oxide). The material forming the insulating layer 172 (e.g., silicon dioxide) is then deposited. Pillar holes are then etched in the insulating layer 172 with the layer 188 acting as an etch stop. An adhesion layer comprising indium tin oxide, nickel, or other suitable material can be deposited in the pillar holes to aid in providing an ohmic electrical connection between the pillars 184 and the layer 188. Pillar holes are then filled with the pillar material by deposition or another suitable process. The surface of the resulting structure after the pillar fill process is planarized by a chemical-mechanical polish process or another planarization process. Planarization is followed by deposition of the mirror layer 168.

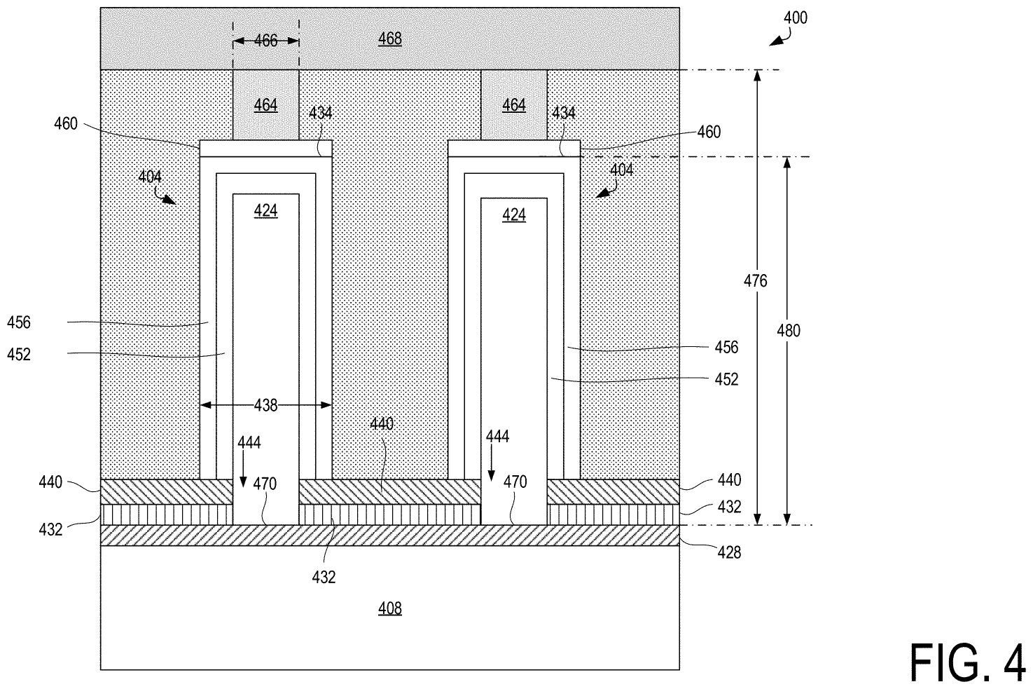

FIG. 4 illustrates an example structure comprising nanowire LEDs distanced from a mirror layer and electrically coupled to the mirror layer by vias. The structure 400 is similar to structure 100 but with the LEDs being nanowire LEDs instead of pyramid LEDs. The structure 400 comprises LEDs 404, which can also be referred to as micro LEDs, located on a substrate 408. Vias 464 electrically couple the LEDs 404 to a mirror layer 468. The substrate 408 can be a silicon-on-sapphire substrate, a silicon substrate, or comprise a material that can be a base or substrate for the LEDs 404. The substrate 408 can be part of a wafer upon which a large number of LEDs 404 have been manufactured. The substrate 408 can be considered to be a source substrate as it is the substrate on which the LEDs 404 are formed and the substrate from which the LEDs 404 are transferred to another component. The LEDs 404 are nanowire LEDs. A nanowire LED 404 comprises a nanowire core 424, a quantum well layer 452, and a p-electrode layer 456. The individual LEDs 404 have an end 434 positioned proximate to and distanced from the mirror layer 468 and an end 470 distal to the mirror layer 468.

In some embodiments, the nanowire cores 424 can have a width 438 in the range of about 3-10 um. In some embodiments, the nanowire cores 414 can have a width of about 3 um, 5 um, or 10 um, or another size. In some embodiments, the width 438 of the nanowire cores 424 can be in the range of about 100-800 nm. The LEDs 404 can have a round, square, hexagonal, or any other cross-sectional shape.

A layer 428 positioned between the LEDs 404 and the substrate 408 can function as a nucleation layer for growing the nanowire cores 424. The layer 428 can comprise aluminum and nitrogen and can be aluminum nitride, aluminum scandium nitride, or another material. A release layer 432 positioned adjacent to the layer 428 can be utilized in releasing the LEDs 404 from the substrate 408 via laser irradiation ablation, as described above in regards to release layer 132 in FIG. 1. The release layer 432 can comprise titanium nitride, niobium nitride, tantalum nitride, another metal nitride suitable, or any other material suitable for use in releasing the LEDs 404 from the substrate 408 via laser irradiation. In some embodiments, the thickness of the release layer 432 can be in the range of about 5-50 nm. In other embodiments, the thickness of the release layer 432 can be in the range of about 10-30 nm.

Layer 440 functions as a mask used in the formation of the nanowire cores 424. That is, the layer 440 can be patterned as illustrated in FIG. 4 via a photolithography process. Layer 440 can comprise silicon and nitrogen and can be silicon nitride (e.g., Si₃N₄) or any other material that can function as a mask for the subsequent growth of gallium nitride. Layer 440 as patterned in FIG. 4 defines cavities 444.

Nanowire cores 424 are grown from the cavities 444 and are grown out of the layer 428. In other embodiments, the layer 432 is not etched during the photolithography process that creates the holes in the layer 440 and the nanowire cores are grown out of the release layer 432. Nanowire cores 424 can comprise n-type gallium nitride or another material that can function as a base to grow quantum wells that result in light emission from the LEDs 404. In some embodiments, the nanowire cores 424 can be grown using an MOCVD process or another process that can grow nanowire cores 424.

Quantum wells 452 are positioned adjacent to the nanowire cores 424. The quantum well layers 452 can comprise indium, gallium, and nitride and can be indium gallium nitride/gallium nitride quantum wells—layers comprising two or more gallium nitride layers with an indium gallium nitride layer positioned between adjacent gallium nitride layers. The quantum wells 452 can determine the color of light generated by the LEDs 404. In some embodiments, the quantum wells 452 can be grown using an MOVPE process or another process that can grow quantum wells 452 over the nanowire cores 424. In some embodiments, an aluminum gallium nitride layer is positioned between the quantum wells 452 and the nanowire core 424. In some embodiments, the aluminum gallium nitride layer can be undoped aluminum gallium nitride.

P-electrode layers 456 are positioned adjacent to the quantum wells 452. The p-electrode layers 456 can comprise gallium and nitride and can be p-doped gallium nitride or other suitable material. The p-electrode layers 456 can help to provide holes to the quantum wells 452 to allow for the emission of light. In some embodiments, the p-electrode layers 456 can be grown using an MOVPE process or another that can grow p-electrode layers 456 over the quantum wells 452. Adhesion layers 460 are positioned adjacent to ends 434 of the LEDs 404 to aid in creating ohmic contacts to the p-gallium nitride layers 456. The adhesion layers 460 can comprise nickel, palladium, platinum, silver, or another material that can aid in creating an ohmic contact to the p-gallium nitride layers 456. In some embodiments, the adhesion layers 460 can be created using physical vapor deposition (PVD) or another suitable process.

The p-electrode layers 456 and the n-doped nanowire cores 424 can be referred to as LED electrodes, with the p-electrode layers 456 being the anode electrodes and the n-doped nanowire cores 424 being the cathode electrodes of the LEDs 404.

Vias 464 are positioned adjacent to the adhesion layers 460 and connect the adhesion layers 460 to a layer 468 positioned adjacent to the vias 464 and an insulating layer 472. The insulating layer 472 fills spaces between the layer 440, the LEDs 404, the vias 464 and the layer 468. The vias 464 can comprise copper, nickel, the same material as layer 468 (e.g., aluminum and silicon), or other suitable material. The vias 464 can have a width 466 in the range of about 200-500 nm.

The layer 468 reflects visible light emitted by the LEDs 404 back toward the nanowire cores 424 and thus acts as an optical mirror that can increase the light extraction efficiency of the LEDs 404. The layer 468 can be referred to as a mirror layer. In embodiments where the LEDs 404 are used in pixels of a direct view display, the layer 468 reflects light emitted by the LEDs toward a viewer of the display. The layer 468 can comprise aluminum and silicon in ratios in the range of about 97-99% aluminum to about 1-3% silicon. The layer 468 can comprise aluminum and silicon in other ratios or comprise other suitable materials that allow the layer 468 to operate as an optical mirror for light emitted by the LEDs 404. In some embodiments, the layer 468 can be added over the insulating layer 472 and the vias 464 by sputtering, PVD, or another suitable process.

The insulating layer 472 comprises silicon dioxide, silicon oxynitride, carbon-doped oxide, or another suitable electrically insulating material. The insulating layer 472 can be added via plasma enhanced chemical vapor deposition (PECVD) or another suitable process. A planarization process such as chemical-mechanical polish (CMP) can be used to create a substantially uniform mirror height over a substrate area, the mirror height or optical cavity height over a substrate area, the mirror height or optical cavity as measured from the layer 468 to the end 470 of an LED (or to the surface of the layer abutting the nanowire core 424 (e.g., layer 428)). The presence of the vias 464 allows the LEDs 404 to be positioned proximate to and distanced from the layer 468.

In some embodiments, a mirror height or optical cavity height 476 is greater than a nanowire LED height 480 as measured from an LED end 470 to an LED end 434. In some embodiments, the mirror height 176 can be substantially 1.1 times the nanowire LED height 480. In some embodiments, the nanowire LED height can be in the range of about 1-10 um.

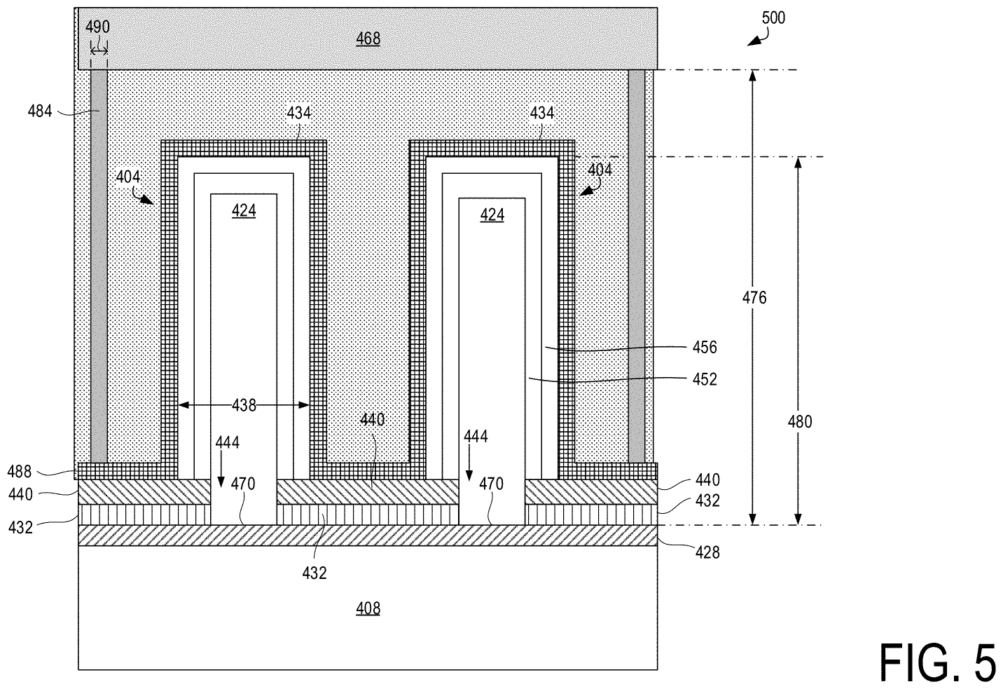

FIG. 5 illustrates an example structure comprising nanowire LEDs distanced from a mirror layer and electrically coupled to the mirror layer by pillars. The structure 500 is similar to the structure 400 of FIG. 4 but with pillars 484 and a layer 488 that extends over the LEDs 404 providing the electrical coupling between the layer 468 to the LEDs 404 instead of vias (e.g., 464). The layer 488 is positioned between the insulating layer 472 and the p-electrode layer 456 and is transparent to allow light emitted by the LEDs 404 to reach the layer 468 and light reflected from the layer 468 to reach the nanowire cores 424. The layer 488 can comprise indium tin oxide (ITO) or other suitable conductive material that is transparent to visible light. The pillars 484 can comprise copper, nickel, the same material is layer 468 (e.g., aluminum and silicon), or other suitable material.

In some embodiments, the pillars 484 can have a width 490 about 1000 nm. FIG. 5 illustrates two pillars 484 providing electrical coupling between the layer 468 and the p-gallium nitride electrodes for two LEDs 404. This pillar frequency (one pillar for two nanowire LEDs) can be repeated throughout an array of LEDs that the LEDs 404 are a part of In other embodiments, pillars could be placed between immediately adjacent nanowire LEDs or positioned with three, four, five, or any other number of nanowire LEDs between pillars. Further, pillars could be positioned with N nanowire LEDs between pillars in more than one dimension. That is, pillars could be placed with three nanowire LEDs between pillars in a first dimension (e.g., an x-dimension) and with three nanowire LEDs between pillars in a second dimension that is orthogonal to the first dimension (e.g., a y-dimension). It is not necessary that pillars be arranged in a periodic or regular fashion. Pillars can be arranged in any configuration among a plurality of nanowire LEDs. The pillars 484 can be formed in the same manner as the pillars 184 as described above.

In some embodiments, micro LEDs (e.g., 104, 404) that emit different colors of light can be formed on a substrate (e.g., 108, 408). For example, in some embodiments, LEDs that emit red light, LEDs that emit blue light, and LEDs that emit green light can be formed on the same substrate. Being able to transfer LEDs that emit red, green, and blue light from a single source substrate to another component in a single transfer process can result in lower manufacturing costs.

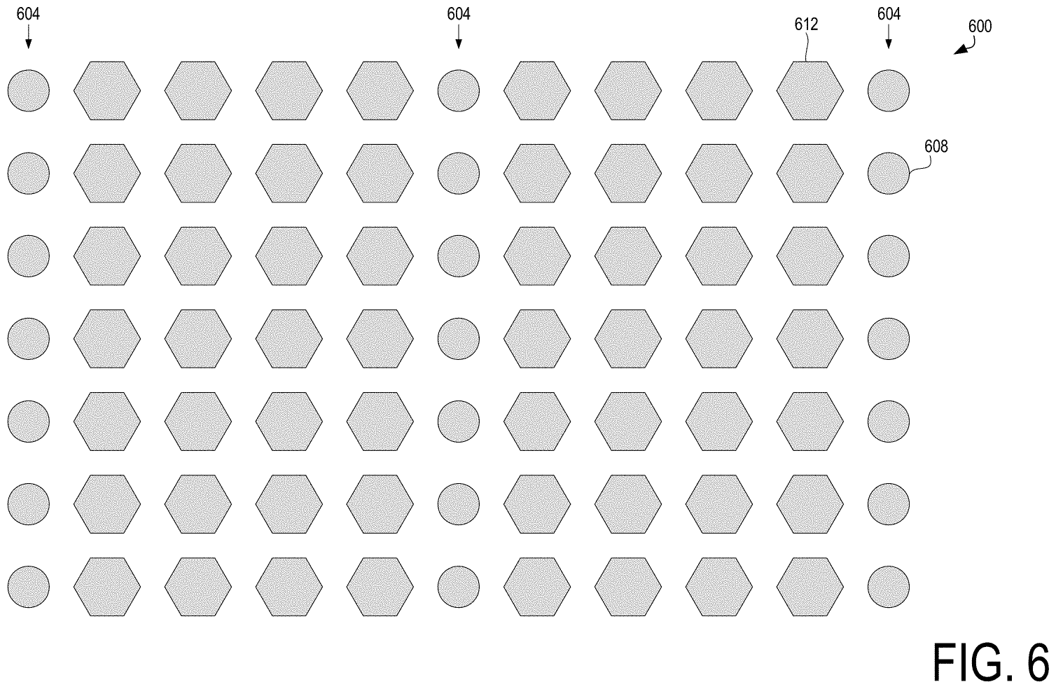

FIG. 6 illustrates an example arrangement of pillars among a plurality of LEDs. The arrangement 600 comprises columns 604 of pillars 608 arranged among a plurality of LEDs 612 having a hexagonal base (pyramid LEDs) or hexagonal cross-section (nanowire LEDs), with four columns of LEDs positioned between pillar columns 604.

The utilization of vias or pillars to electrically couple a mirror layer to LEDs allows the mirror height to be tuned for a particular LED structure (e.g., structure 100, 400) to reduce the adverse impact on LED release yield of destructive interference caused by the mirror layer reflecting LED-emitted light to a release layer. With reference to FIG. 1, taller or shorter vias 164 can be formed in thicker or thinner insulating layer 172, to increase or decrease the mirror height 176, respectively. A tuned mirror height can depend on, for example, an LED height and/or release layer material, and a tuned mirror height can be determined based on, for example, manufacturing results and/or simulation results indicating the dependency of LED release yield on mirror height.

Although the technologies described herein can improve the release yield of pyramid and nanowire LEDs, they can be applied to any type of 3D light-emitting device (any light-emitting device with electrodes that are not substantially coplanar).

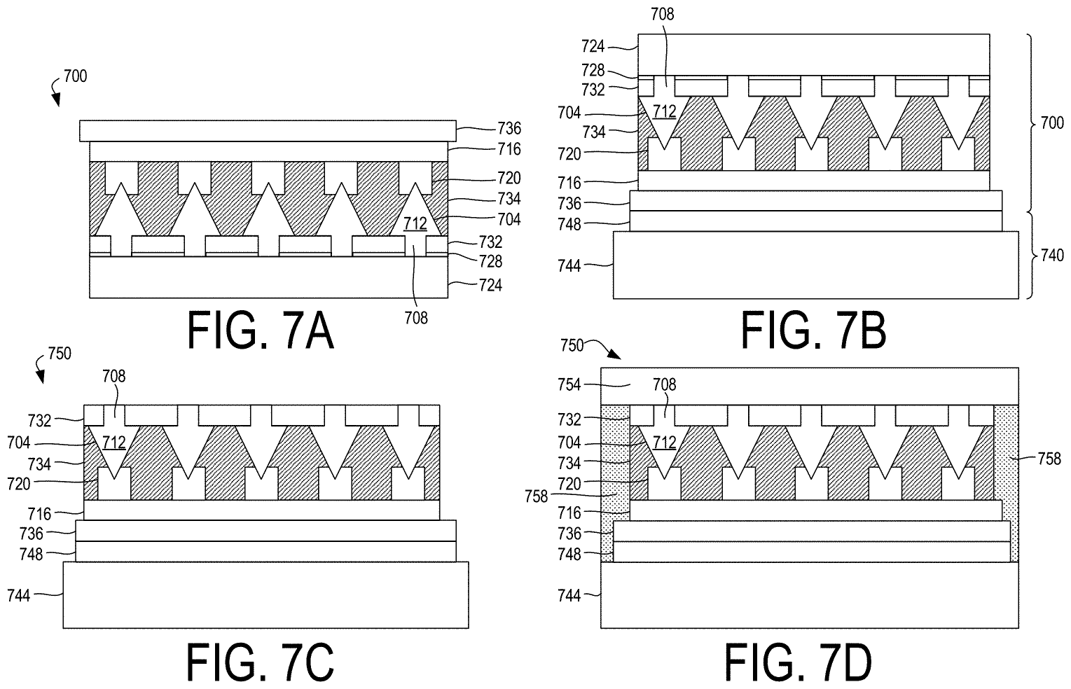

FIGS. 7A-7D illustrate an example process of transferring pyramid LEDs electrically coupled to a mirror layer with vias from a source substrate to a display backplane. FIG. 7A illustrates a structure 700 comprising pyramid LEDs 704 located on a substrate 724. The pyramid LEDs 704 comprise stems 708 and bodies 712. The pyramid LEDs 704 are electrically coupled to a mirror layer 716 by vias 720. A release layer 728 and one or more mask layers 732 are positioned between the LED bodies 712 and the substrate 724 and an insulating layer 734 is positioned between the mirror layer 716 and the mask layers 732. The structure comprises a first pad 736 for attaching the structure 700 to another component. The first pad 736 can comprise copper or another suitable material for attaching the structure 700 to another component.

FIG. 7B illustrates the structure 700 flipped and attached to a display backplane structure 740. The display backplane structure 740 comprises a display backplane 744 and a second pad 748 to provide a physical and electrical connection between the display backplane structure 740 and the structure 700 and aids in facilitating the transfer of the LEDs 704 to the display backplane structure 740. The second pad 748 comprises copper or another suitable material for connecting the display backplane structure 740 to the structure 700.

FIG. 7C illustrates a structure 750 comprising the structure 700 and the display backplane structure 740 (minus the substrate 724) after release of the LEDs 704 from the substrate 724 through laser irradiation of the release layer 728. Through attachment of the structure 700 to the display backplane structure 740 and subsequent laser ablation of the release layer 728, the LEDs 704 are transferred from the substrate 724 to the display backplane structure 740. The LEDs 704 can be part of a pixel of a direct view display that comprises the structure 750.

FIG. 7D illustrates the structure 750 after addition of a transparent layer 754 and a fill layer 758. The layer 754 can comprise indium tin oxide or any other transparent layer. The LEDs 704 can comprise one or more LEDs that emit red light (red LEDs), one or more LEDs that emit green light (green LEDs), and one or more LEDs that emit blue light (blue LEDs) and the layer 754 can comprise interconnects that connect to stems 708. Application of voltage differentials across the LEDs 704 can cause the LEDs to collectively emit light and varying the voltage differentials across the red, blue, and green LEDs can vary the color and brightness of the light collectively emitted by the LEDs 704.

Although FIGS. 7A-7D illustrate the transfer of pyramid LEDs electrically coupled to a mirror layer by vias, structures comprising pyramid LEDs electrically coupled to a mirror layer by pillars could be transferred in a similar fashion. Structures comprising nanowire LEDs electrically coupled to a mirror layer by vias or pillars can be similarly transferred to a display backplane as well. Further, structures comprising light emitting elements connected to a mirror layer by vias or pillars could be transferred to components other than a display backplane. For example, such LED structures could be transferred for use in optical interconnect components.

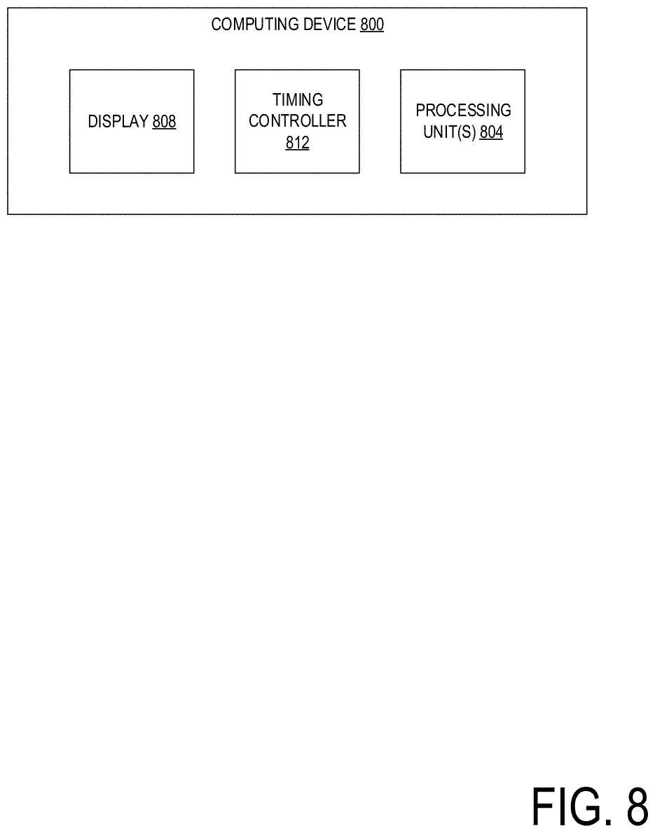

FIG. 8 is an example computing system comprising structures with LEDs electrically coupled to a mirror layer by vias or pillars. The computing system 800 comprises one or more processing units 804, a display 808, and a timing controller 812. The processing units 804 can comprise any type of processing unit described or referenced herein (e.g., an SoC) and can cause content to be displayed at the display 808. The processing units 804 can cause content (e.g., images, videos) to be displayed at the display 808 by generating video data that is provided to the timing controller 812. The timing controller 812 can convert the video data into signals that drive the display 808. The display 808 can comprise a plurality of pixels with individual pixels comprising one or more LEDs electrically coupled to a mirror layer by a via or pillar as described herein. The computing system 800 can further comprise a housing. In some embodiments, the display 808 and the one or more processing units 804 are located within the housing. In other embodiments, the one or more processing units 804 are located within the housing and the display 808 is a stand-alone display external to the housing and can communicate with the one or more processing units via a wired or wireless connection.

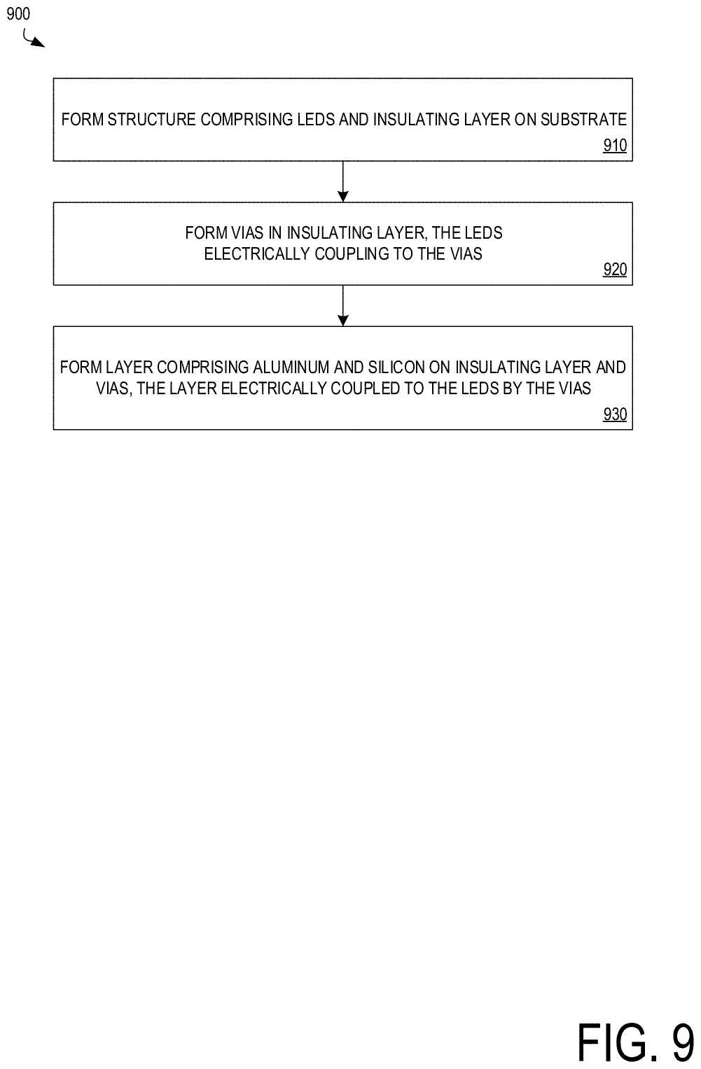

FIG. 9 is a first example method for forming structures comprising LEDs. At 910 in the method 900, a structure is formed on a substrate, the structure comprising a plurality of light-emitting diodes (LEDs) and an insulating layer filling spaces between adjacent LEDs and covering the LEDs. At 920, a plurality of vias is formed in the insulating layer, individual of the LEDs electrically coupling to one of the vias. At 930, a first layer is formed comprising aluminum and silicon on the insulating layer and the vias, the first layer electrically coupled to the LEDs by the vias.

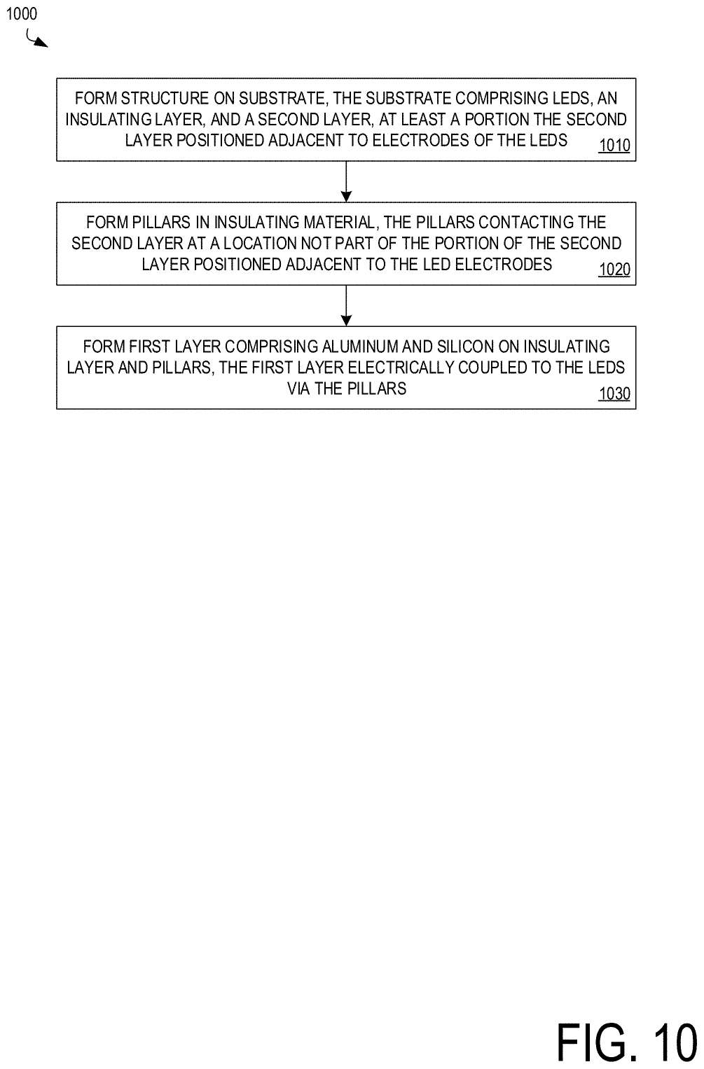

FIG. 10 is a second example method for forming structures comprising LEDs. At 1010 in the method 1000, a structure is formed on a substrate. The structure comprises a plurality of light-emitting diodes (LEDs), individual of the LEDs comprising an electrode; an insulating layer filling spaces between adjacent LEDs and covering the LEDs; and a second layer, at least a portion of the second layer positioned adjacent to the electrodes. At 1020, a plurality of pillars is formed in the insulating material, individual of the pillars contacting the second layer at a location that is not part of the portion of the second layer positioned adjacent to the electrodes. At 1030, a first layer comprising aluminum and silicon on the insulating layer and the pillars is formed, the first layer electrically connected to the LEDs via the pillars.

The technologies described herein can be performed by or implemented in any of a variety of computing systems, including mobile computing systems (e.g., smartphones, handheld computers, tablet computers, laptop computers, portable gaming consoles, 2-in-1 convertible computers, portable all-in-one computers), non-mobile computing systems (e.g., desktop computers, servers, workstations, stationary gaming consoles, set-top boxes, smart televisions, rack-level computing solutions (e.g., blade, tray, or sled computing systems)), and embedded computing systems (e.g., computing systems that are part of a vehicle, smart home appliance, consumer electronics product or equipment, manufacturing equipment). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

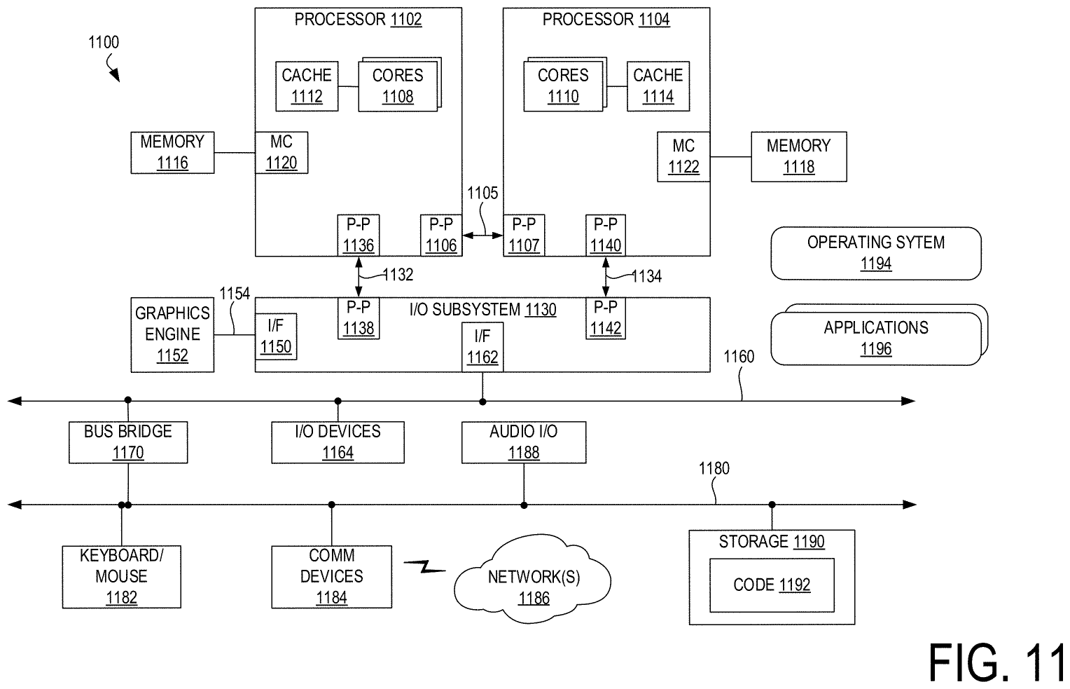

FIG. 11 is a block diagram of an example computing system in which technologies described herein may be implemented. Generally, components shown in FIG. 11 can communicate with other shown components, although not all connections are shown, for ease of illustration. The computing system 1100 is a multiprocessor system comprising a first processor unit 1102 and a second processor unit 1104 comprising point-to-point (P-P) interconnects. A point-to-point (P-P) interface 1106 of the processor unit 1102 is coupled to a point-to-point interface 1107 of the processor unit 1104 via a point-to-point interconnection 1105. It is to be understood that any or all of the point-to-point interconnects illustrated in FIG. 11 can be alternatively implemented as a multi-drop bus, and that any or all buses illustrated in FIG. 11 could be replaced by point-to-point interconnects. The processor units 1102 and 1104 comprise multiple processor cores. Processor unit 1102 comprises processor cores 1108 and processor unit 1104 comprises processor cores 1110.

Processor units 1102 and 1104 further comprise cache memories 1112 and 1114, respectively. The cache memories 1112 and 1114 can store data (e.g., instructions) utilized by one or more components of the processor units 1102 and 1104, such as the processor cores 1108 and 1110. The cache memories 1112 and 1114 can be part of a memory hierarchy for the computing system 1100. For example, the cache memories 1112 can locally store data that is also stored in a memory 1116 to allow for faster access to the data by the processor unit 1102. In some embodiments, the cache memories 1112 and 1114 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Although the computing system 1100 is shown with two processor units, the computing system 1100 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 1100 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 1102 and 1104 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Processor units 1102 and 1104 further comprise memory controller logic (MC) 1120 and 1122. As shown in FIG. 11, MCs 1120 and 1122 control memories 1116 and 1118 coupled to the processor units 1102 and 1104, respectively. The memories 1116 and 1118 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 1120 and 1122 are illustrated as being integrated into the processor units 1102 and 1104, in alternative embodiments, the MCs can be external to a processor unit.

Processor units 1102 and 1104 are coupled to an Input/Output (I/O) subsystem 1130 via point-to-point interconnections 1132 and 1134. The point-to-point interconnection 1132 connects a point-to-point interface 1136 of the processor unit 1102 with a point-to-point interface 1138 of the I/O subsystem 1130, and the point-to-point interconnection 1134 connects a point-to-point interface 1140 of the processor unit 1104 with a point-to-point interface 1142 of the I/O subsystem 1130. Input/Output subsystem 1130 further includes an interface 1150 to couple the I/O subsystem 1130 to a graphics engine 1152. The I/O subsystem 1130 and the graphics engine 1152 are coupled via a bus 1154.

The Input/Output subsystem 1130 is further coupled to a first bus 1160 via an interface 1162. The first bus 1160 can be a Peripheral Component Interconnect Express (PCIe) bus or any other type of bus. Various I/O devices 1164 can be coupled to the first bus 1160. A bus bridge 1170 can couple the first bus 1160 to a second bus 1180. In some embodiments, the second bus 1180 can be a low pin count (LPC) bus. Various devices can be coupled to the second bus 1180 including, for example, a keyboard/mouse 1182, audio I/O devices 1188, and a storage device 1190, such as a hard disk drive, solid-state drive, or another storage device for storing computer-executable instructions (code) 1192 or data. The code 1192 can comprise computer-executable instructions for performing methods described herein. Additional components that can be coupled to the second bus 1180 include communication device(s) 1184, which can provide for communication between the computing system 1100 and one or more wired or wireless networks 1186 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 1102.11 standard and its supplements).

In embodiments where the communication devices 1184 support wireless communication, the communication devices 1184 can comprise wireless communication components coupled to one or more antennas to support communication between the computing system 1100 and external devices. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The system 1100 can comprise removable memory such as flash memory cards (e.g., SD (Secure Digital) cards), memory sticks, Subscriber Identity Module (SIM) cards). The memory in system 1100 (including caches 1112 and 1114, memories 1116 and 1118, and storage device 1190) can store data and/or computer-executable instructions for executing an operating system 1194 and application programs 1196. Example data includes web pages, text messages, images, sound files, and video data to be sent to and/or received from one or more network servers or other devices by the system 1100 via the one or more wired or wireless networks 1186, or for use by the system 1100. The system 1100 can also have access to external memory or storage (not shown) such as external hard drives or cloud-based storage.

The operating system 1194 can control the allocation and usage of the components illustrated in FIG. 11 and support the one or more application programs 1196. The application programs 1196 can include common computing system applications (e.g., email applications, calendars, contact managers, web browsers, messaging applications) as well as other computing applications.

In some embodiments, a hypervisor (or virtual machine manager) operates on the operating system 1194 and the application programs 1196 operate within one or more virtual machines operating on the hypervisor. In these embodiments, the hypervisor is a type-2 or hosted hypervisor as it is running on the operating system 1194. In other hypervisor-based embodiments, the hypervisor is a type-1 or “bare-metal” hypervisor that runs directly on the platform resources of the computing system 1194 without an intervening operating system layer.

In some embodiments, the applications 1196 can operate within one or more containers. A container is a running instance of a container image, which is a package of binary images for one or more of the applications 1196 and any libraries, configuration settings, and any other information that one or more applications 1196 need for execution. A container image can conform to any container image format, such as Docker®, Appc, or LXC container image formats. In container-based embodiments, a container runtime engine, such as Docker Engine, LXU, or an open container initiative (OCI)-compatible container runtime (e.g., Railcar, CRI-O) operates on the operating system (or virtual machine monitor) to provide an interface between the containers and the operating system 1194. An orchestrator can be responsible for management of the computing system 1100 and various container-related tasks such as deploying container images to the computing system 1194, monitoring the performance of deployed containers, and monitoring the utilization of the resources of the computing system 1194.

The computing system 1100 can support various additional input devices, such as a touchscreen, microphone, monoscopic camera, stereoscopic camera, trackball, touchpad, trackpad, proximity sensor, light sensor, electrocardiogram (ECG) sensor, PPG (photoplethysmogram) sensor, galvanic skin response sensor, and one or more output devices, such as one or more speakers or displays. A display can comprise any of the LED structures described herein. Other possible input and output devices include piezoelectric and other haptic I/O devices. Any of the input or output devices can be internal to, external to, or removably attachable with the system 1100. External input and output devices can communicate with the system 1100 via wired or wireless connections.

In addition, the computing system 1100 can provide one or more natural user interfaces (NUIs). For example, the operating system 1194 or applications 1196 can comprise speech recognition logic as part of a voice user interface that allows a user to operate the system 1100 via voice commands. Further, the computing system 1100 can comprise input devices and logic that allows a user to interact with computing the system 1100 via body, hand, or face gestures.

The system 1100 can further include at least one input/output port comprising physical connectors (e.g., USB, IEEE 1394 (FireWire), Ethernet, RS-232), a power supply (e.g., battery), a global satellite navigation system (GNSS) receiver (e.g., GPS receiver); a gyroscope; an accelerometer; and/or a compass. A GNSS receiver can be coupled to a GNSS antenna. The computing system 1100 can further comprise one or more additional antennas coupled to one or more additional receivers, transmitters, and/or transceivers to enable additional functions.

In addition to those already discussed, integrated circuit components, integrated circuit constituent components, and other components in the computing system 794 can communicate with interconnect technologies such as Intel® QuickPath Interconnect (QPI), Intel® Ultra Path Interconnect (UPI), Computer Express Link (CXL), cache coherent interconnect for accelerators (CCIX®), serializer/deserializer (SERDES), Nvidia® NVLink, ARM Infinity Link, Gen-Z, or Open Coherent Accelerator Processor Interface (OpenCAPI). Other interconnect technologies may be used and a computing system 794 may utilize more or more interconnect technologies. Any of the LED structures described herein can be incorporated into an optical interconnect.

It is to be understood that FIG. 11 illustrates only one example computing system architecture. Computing systems based on alternative architectures can be used to implement technologies described herein. For example, instead of the processors 1102 and 1104 and the graphics engine 1152 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 11. Moreover, the illustrated components in FIG. 11 are not required or all-inclusive, as shown components can be removed and other components added in alternative embodiments.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a plurality of light-emitting diodes (LEDs); a first layer comprising aluminum and silicon, individual of the LEDs positioned proximate to and distanced from the first layer; and a plurality of vias, individual of the vias electrically coupling one of the LEDs to the first layer.

Example 2 is an apparatus comprising: a plurality of light-emitting diodes (LEDs); a first layer comprising aluminum and silicon, individual of the LEDs comprising an electrode positioned proximate to and distanced from the first layer; a second layer, at least a portion of the second layer positioned adjacent to the LED electrodes; and one or more pillars, individual of the pillars contacting the second layer at a location that is not part of the portion of the second layer positioned adjacent to the LED electrodes, the pillars and the second layer electrically coupling the first layer to the LEDs.

Example 3 comprises the apparatus of example 2, wherein the second layer comprises indium tin oxide.

Example 4 comprises the apparatus of any one of examples 1-3, wherein the LEDs are pyramid LEDs.

Example 5 comprises the apparatus of any one of examples 1-3, wherein the LEDs are nanowire LEDs.

Example 6 comprises the apparatus of any one of examples 1-5, wherein, for individual of the LEDs, the individual LED comprises a first end that is distal to the first layer and a second end that is proximate to the first layer, a distance from the first end of the individual LED to the first layer being substantially 1.1 times a height of the individual LED as measured from the first end of the individual LED to the second end of the individual LED.

Example 7 comprises the apparatus of any one of examples 1-6, further comprising a substrate, wherein the LEDs are located on the substrate.

Example 8 comprises the apparatus of example 7, wherein a release layer is positioned between the LEDs and the substrate.

Example 9 comprises the apparatus of any one of examples 1-6, wherein the apparatus is a display.

Example 10 comprises the apparatus of any one of examples 1-6, wherein the apparatus is an optical interconnect.

Example 11 is a method comprising: forming a structure on a substrate, the structure comprising a plurality of light-emitting diodes (LEDs) and an insulating layer filling spaces between adjacent LEDs and covering the LEDs; forming a plurality of vias in the insulating layer, individual of the LEDs connecting to one of the vias; and forming a first layer comprising aluminum and silicon on the insulating layer and the vias, the first layer electrically coupled to the LEDs by the vias.

Example 12 is a method comprising: forming a structure on a substrate, the structure comprising: a plurality of light-emitting diodes (LEDs), individual of the LEDs comprising an electrode; an insulating layer filling spaces between adjacent LEDs and covering the LEDs; and a second layer, at least a portion of the second layer positioned adjacent to the electrodes; forming a plurality of pillars in the insulating layer, individual of the pillars contacting the second layer at a location that is not part of the portion of the second layer positioned adjacent to the electrodes; and forming a first layer comprising aluminum and silicon on the insulating layer and the pillars, the first layer electrically connected to the LEDs via the pillars.

Example 13 comprises the method of example 11 or 12, wherein the LEDs are pyramid LEDs.

Example 14 comprises the method of example 11 or 12, wherein the LEDs are nanowire LEDs.

Example 15 comprises the method of any one of examples 11-14, wherein, for individual of the LEDs, the individual LED comprises a first end that is distal to the first layer, a distance from the first end of the individual LED to the first layer being substantially 1.1 times a height of the individual LEDs as measured from the first end of the individual LED to a second end of the LED that is proximate to the first layer.

Example 16 comprises the method of any one of examples 11-15, wherein a release layer is positioned between the LEDs and the substrate.

Example 17 is a display comprising: a plurality of light-emitting diodes (LEDs); a plurality of pixels comprising the LEDs; a first layer comprising aluminum and silicon, individual of the LEDs positioned proximate to and distanced from the first layer; and a plurality of vias, individual of the vias electrically coupling one of the LEDs to the first layer.

Example 18 is a display comprising: a plurality of light-emitting diodes (LEDs); a plurality of pixels comprising the LEDs; a first layer comprising aluminum and silicon, individual of the LEDs having an electrode positioned proximate to and distanced from the first layer; a second layer, at least a portion of the second layer positioned adjacent to the electrodes of the LEDs; and one or more pillars, individual of the pillars contacting the second layer at a location where the second layer is not adjacent to one of the electrodes of the LEDs, the pillars and the second layer electrically coupling the first layer to the LEDs.

Example 19 comprises the display of example 18, wherein the second layer comprises indium tin oxide.

Example 20 comprises the display of any one of examples 17-19, wherein the LEDs are pyramid LEDs.

Example 21 comprises the display of any one of examples 17-19, wherein the LEDs are nanowire LEDs.

Example 22 comprises the display of any one of examples 17-21, wherein, for individual of the LEDs, the individual LED comprises a first end that is distal to the first layer and a second end that is proximate to the first layer, a distance from the first end of the individual LED to the first layer being substantially 1.1 times a height of the individual LED as measured from the first end of the individual LED to the second end of the individual LED.

Example 23 is a computing device comprising: a display comprising: a plurality of light-emitting diodes (LEDs); a plurality of pixels comprising the LEDs; a first layer comprising aluminum and silicon, individual of the LEDs positioned proximate to and distanced from the first layer; and a plurality of vias, individual of the vias electrically coupling one of the LEDs to the first layer; and one or more processing units to cause content to be displayed at the display.

Example 24 is a computing device comprising: a display comprising: a plurality of light-emitting diodes (LEDs); a plurality of pixels comprising the LEDs; a first layer comprising aluminum and silicon, individual of the LEDs having an electrode positioned proximate to and distanced from the first layer; a second layer, at least a portion of the second layer positioned adjacent to the electrodes of the LEDs; and one or more pillars, individual of the pillars contacting the second layer at a location where the second layer is not adjacent to one of the electrodes of the LEDs, the pillars and the second layer electrically coupling the first layer to the LEDs; and one or more processing units to cause content to be displayed at the display.

Example 25 comprises the computing device of example 24, wherein the second layer comprises indium tin oxide.

Example 26 comprises the computing device of any one of examples 23-25, wherein the LEDs are pyramid LEDs.

Example 27 comprises the computing device of any one of examples 23-25, wherein the LEDs are nanowire LEDs.

Example 28 comprises the computing device of any one of examples 23-27, wherein, for individual of the LEDs, the individual LED comprises a first end that is distal to the first layer, a distance from the first end of the individual LED to the first layer being substantially 1.1 times a height of the individual LEDs as measured from the first end of the individual LED to a second end of the LED that is proximate to the first layer.

Example 29 comprises the computing device of any one of examples 23-28, further comprising a housing, wherein the display and the one or more processing units are located within the housing.

Example 30 comprises the computing device of any one of examples 23-28, further comprising a housing, wherein the one or more processing units are located within the housing and the display is located external to the housing.

Example 31 is an apparatus comprising: a plurality of light-emitting diodes (LEDs); a first layer comprising aluminum and silicon, individual of the LEDs having an electrode positioned proximate to and distanced from the first layer; and an electrical coupling means to electrically couple the LEDs to the first layer.

Example 32 comprises the apparatus of example 31, wherein the LEDs are pyramid LEDs.

Example 33 comprises the apparatus of example 31, wherein the LEDs are nanowire LEDs.

1. An apparatus comprising:
a plurality of light-emitting diodes (LEDs);
a first layer comprising aluminum and silicon, individual of the LEDs positioned proximate to and distanced from the first layer; and
a plurality of vias, individual of the vias electrically coupling one of the LEDs to the first layer.

2. The apparatus of claim 1, wherein the LEDs are pyramid LEDs.

3. The apparatus of claim 1, wherein the LEDs are nanowire LEDs.

4. The apparatus of claim 1, wherein, for individual of the LEDs, the individual LED comprises a first end that is distal to the first layer and a second end that is proximate to the first layer, a distance from the first end of the individual LED to the first layer being substantially 1.1 times a height of the individual LED as measured from the first end of the individual LED to the second end of the individual LED.

5. The apparatus of claim 1, further comprising a substrate, wherein the LEDs are located on the substrate.

6. The apparatus of claim 5, wherein a release layer is positioned between the LEDs and the substrate.

7. The apparatus of claim 1, wherein the apparatus is a display.

8. The apparatus of claim 1, wherein the apparatus is an optical interconnect.

9. A method comprising:
forming a structure on a substrate, the structure comprising a plurality of light-emitting diodes (LEDs) and an insulating layer filling spaces between adjacent LEDs and covering the LEDs;
forming a plurality of vias in the insulating layer, individual of the LEDs connecting to one of the vias; and
forming a first layer comprising aluminum and silicon on the insulating layer and the vias, the first layer electrically coupled to the LEDs by the vias.

10. The method of claim 9, wherein the LEDs are pyramid LEDs.

11. The method of claim 9, wherein the LEDs are nanowire LEDs.

12. The method of claim 9, wherein, for individual of the LEDs, the individual LED comprises a first end that is distal to the first layer, a distance from the first end of the individual LED to the first layer being substantially 1.1 times a height of the individual LEDs as measured from the first end of the individual LED to a second end of the LED that is proximate to the first layer.

13. The method of claim 9, wherein a release layer is positioned between the LEDs and the substrate.

14. A display comprising:
a plurality of light-emitting diodes (LEDs);
a plurality of pixels comprising the LEDs;
a first layer comprising aluminum and silicon, individual of the LEDs positioned proximate to and distanced from the first layer; and
a plurality of vias, individual of the vias electrically coupling one of the LEDs to the first layer.

15. The display of claim 14, wherein the LEDs are pyramid LEDs.

16. The display of claim 14, wherein the LEDs are nanowire LEDs.

17. The display of claim 14, wherein, for individual of the LEDs, the individual LED comprises a first end that is distal to the first layer and a second end that is proximate to the first layer, a distance from the first end of the individual LED to the first layer being substantially 1.1 times a height of the individual LED as measured from the first end of the individual LED to the second end of the individual LED.

18. A computing device comprising:
a display comprising:
a plurality of light-emitting diodes (LEDs);
a plurality of pixels comprising the LEDs;
a first layer comprising aluminum and silicon, individual of the LEDs having an electrode positioned proximate to and distanced from the first layer;
a second layer, at least a portion of the second layer positioned adjacent to the electrodes of the LEDs; and
one or more pillars, individual of the pillars contacting the second layer at a location where the second layer is not adjacent to one of the electrodes of the LEDs, the pillars and the second layer electrically coupling the first layer to the LEDs; and
one or more processing units to cause content to be displayed at the display.

19. The computing device of claim 18, wherein the second layer comprises indium tin oxide.

20. The computing device of claim 18, wherein the LEDs are pyramid LEDs.

21. The computing device of claim 18, wherein the LEDs are nanowire LEDs.

22. The computing device of claim 18, wherein, for individual of the LEDs, the individual LED comprises a first end that is distal to the first layer, a distance from the first end of the individual LED to the first layer being substantially 1.1 times a height of the individual LEDs as measured from the first end of the individual LED to a second end of the LED that is proximate to the first layer.

23. The computing device of claim 18, further comprising a housing, wherein the display and the one or more processing units are located within the housing.

24. The computing device of claim 18, further comprising a housing, wherein the one or more processing units are located within the housing and the display is located external to the housing.
